(19) United States
(12) Patent Application Publication
(10) Pub. No.: US 2024/0213316 A1
(43) Pub. Date: Jun. 27, 2024

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Yi-Ruei JHAN, Keelung (TW); Pei-Yu WANG, Hsinchu (TW); Cheng-Ting CHUNG, Hsinchu (TW); Kuan-Ting PAN, Taipei (TW); Shi Ning JU, Hsinchu (TW); Kuo-Cheng CHIANG, Hsinchu (TW); Chih-Hao WANG, Hsinchu (TW)

(21) Appl. No.: 18/100,714

(22) Filed: Jan. 24, 2023

Related U.S. Application Data
(60) Provisional application No. 63/435,497, filed on Dec. 27, 2022.

(51) Int. Cl. H01L 29/06; H01L 21/8234; H01L 29/423; H01L 29/66; H01L 29/786

(52) U.S. Cl. CPC H01L 29/0673; H01L 21/823412; H01L 21/823418; H01L 21/823481; H01L 29/42392; H01L 29/66545; H01L 29/78696

(57) ABSTRACT

A method for forming a nanosheet device is provided. The method includes epitaxially growing a conformal semiconductor layer from a first stack of semiconductor layers and a second stack of the semiconductor layers. Each of the first and second stack of semiconductor layers includes a plurality of first semiconductor layers and a plurality of second semiconductor layers alternately stacked on each other. A space between the first and second stacks of semiconductor layers is filled with a dielectric fin. The conformal semiconductor layer and the second semiconductor layers may be removed. A metal gate structure is formed over the first semiconductor layers and filling openings created by removal of the conformal semiconductor layer and the second semiconductor layer. A process may be performed on the metal gate structure to form an isolation between the portions of the metal gate structure being separated by a patterning process.

### CROSS-REFERENCE TO RELATED APPLICATIONS

This application claims priority to US Provisional Application Ser. No. 63/435,497 filed Dec. 27, 2022, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

In pursuit of higher device density, higher performance, and lower costs, challenges from both fabrication and design issues have resulted in the development of three-dimensional designs, such as a multi-gate field effect transistor (FET), including a nanosheet FET. In a nanosheet FET, all side surfaces of the channel region are surrounded by the gate electrode, which allows for fuller depletion in the channel region and results in less short-channel effects due to steeper sub-threshold current swing (SS) and smaller drain induced barrier lowering (DIBL). As transistor dimensions are continually scaled down, further improvements of the nanosheet FET are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8 show various stages of manufacturing a semiconductor device in accordance with some embodiments.

FIGS. 9-10 show various stages of manufacturing a semiconductor device structure in accordance with some other embodiments.

FIGS. 11-22 show various stages of manufacturing a semiconductor device structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Along the logic CMOS scaling path, the dimensions of logic standard cells are gradually reduced. In the FinFET structures, the dimensions of a standard cell have been reduced by reducing the cell height, which is defined as the number of metal lines (or tracks) per cell times the metal pitch. New generations of the FinFET have enabled 7.5T, that is, 7.5 tracks in a standard cell, and 6T standards. However, this revolution comes at the expense of drive current and variability. Nanosheet architecture provides larger drive current and allows for a variable device width, which enables some flexibility in design, such that designers can trade off enhanced drive current for reduced area and capacitance as smaller channel width tends to reduce parasitic capacitance between the sheets. Another feature of the nanosheet is its gate-all-around structure. As the conduction channel is completely surrounded by high-k dielectric layer and metal gate, improved gate control over the channel can be achieved for shorter channel lengths.

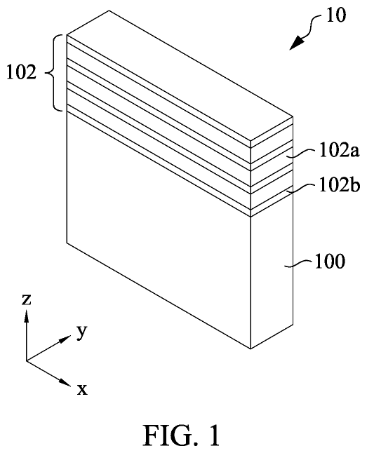

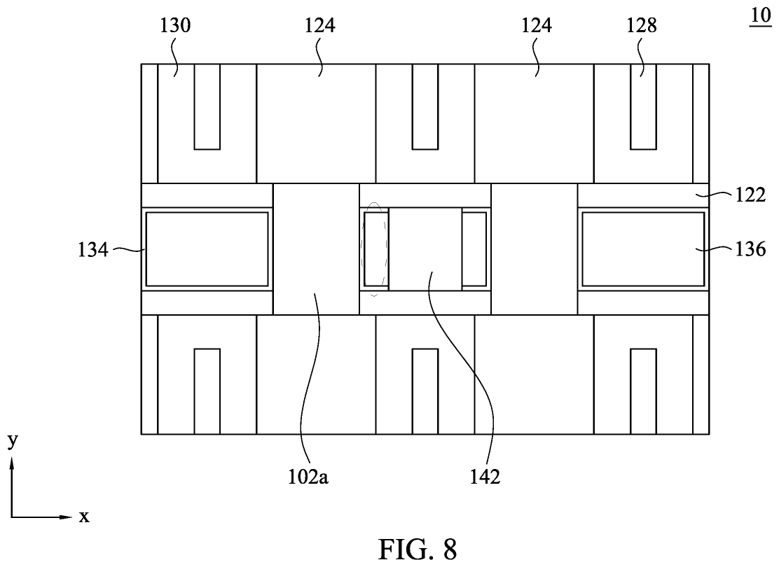

FIGS. 1 to 7 are perspective views showing various stages for manufacturing a nanosheet device. FIG. 8 shows a plane view of the semiconductor device as shown in FIG. 7. In FIG. 1, a substrate 100 is provided. According to one embodiment, the substrate 100 may be a semiconductor substrate. In some embodiments, the substrate 100 includes a single crystalline semiconductor layer on at least the surface of the substrate 100. The substrate 100 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In this embodiment, the substrate 100 is made of Si. In some embodiments, the substrate 100 is a silicon-on-insulator (SOI) substrate, which includes an insulating layer (not shown) disposed between two silicon layers. In one aspect, the insulating layer is an oxide.

One or more buffer layers (not shown) may be formed on the surface of the substrate 100. The buffer layers can serve to gradually change the lattice constant from that of the substrate to that of the source/drain (S/D) regions to be grown on the substrate 100. The buffer layers may be formed from epitaxially grown single crystalline semiconductor materials such as, but not limited to Si, Ge, germanium tin (GeSn), SiGe, GaAs, InSb, GaP, GaSb, InAlAs, InGaAs, GaSbP, GaAsSb, GaN, GaN, and InP. In one embodiment, the substrate 100 includes SiGe buffer layers epitaxially grown on the silicon substrate 100. The germanium concentration of the SiGe buffer layers may increase from 30 atomic percent germanium for the bottom-most buffer layer to 70 atomic percent germanium for the top-most buffer layer. The substrate 100 may include various regions that have been suitably doped with impurities (e.g., p-type or n-type impurities). The dopants are, for example boron for a p-type field effect transistor FET (NFET) and phosphorus for a n-type FET (PFET).

A stack of semiconductor layers 102, including alternately formed first semiconductor layers 102a and second semiconductor layers 102b, is formed on the substrate 100. The first semiconductor layers 102a and the second semiconductor layers 102b are made of semiconductor materials having different etch selectivity and/or oxidation rates. For example, the first semiconductor layers 102a may be made of Si and the second semiconductor layers 102b may be made of SiGe. In some examples, the first semiconductor layers 102a may be made of SiGe and the second semiconductor layers 102b may be made of Si. Alternatively, in some embodiments, either of the semiconductor layers 102a and 102b may be or include other materials such as Ge, SiC, GeAs, GaP, InP, InAs, InSb, GaAsP, AlInAs, AlGaAs, InGaAs, GaInP, GaInAsP, or any combinations thereof. In the embodiment as shown in FIG. 1, the first semiconductor layers 102a are made of Si and the second semiconductor layers 102b is made of Si₁₋ₓGeₓ with x ranging between about 25% and about 50%.

The first semiconductor layers 102a or portions thereof may form nanosheet channel(s) of the semiconductor device structure 10 in subsequent fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 10 May be surrounded by a gate electrode. The semiconductor device structure 10 May include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 102a to define a channel or channels of the semiconductor device structure 10 is further discussed below.

The first and second semiconductor layers 102a and 102b may be formed by any suitable deposition process, such as epitaxy. For example, epitaxial growth of the layers of the stack of semiconductor layers 102 may be performed by a molecular beam epitaxy (MBE) process, a metalorganic chemical vapor deposition (MOCVD) process, and/or other suitable epitaxial growth processes.

The semiconductor layers 102a may define the channels of an FET, such as a n-type FET (NFET) or the channels of a second FET, such as a p-type FET (PFET). The thickness of the first semiconductor layers 102a is chosen based on device performance considerations. In some embodiments, each semiconductor layer 102a has a thickness ranging from about 3 nanometers (nm) to about 10 nm. The second semiconductor layers 102b may eventually be removed and serve to define spaces for a gate stack to be formed therein. Likewise, each of the second semiconductor layers 102b may have a thickness that is equal to, less than, or greater than the thickness of the first semiconductor layers 102a, depending on device performance considerations. In one embodiment, each second semiconductor layers 102b has a thickness that smaller than the thickness of the semiconductor layers 102a.

In FIG. 1, the stack of semiconductor layers 102 includes three first semiconductor layers 102a and four second semiconductor layers 102b. It is appreciated that the numbers of the first and second semiconductor layers 102a and 102b in the stack of semiconductor layers 102 may vary depending on the desired number of nanosheet channels needed for the semiconductor structure 10. It is appreciated that the structure as shown in FIG. 1 may extend along the x-direction and/or the y-direction for forming an array of cell units on the substrate 10. The semiconductor structure 10 is applied to various devices such as a forksheet device which includes a PFET and an NFET arranged side by side at the same level along the x-direction. The semiconductor structure 10 May also be applied to a complementary FET (CFET) device in which an additional stack of semiconductor layers is formed over the stack of semiconductor layers 102 along the z-direction.

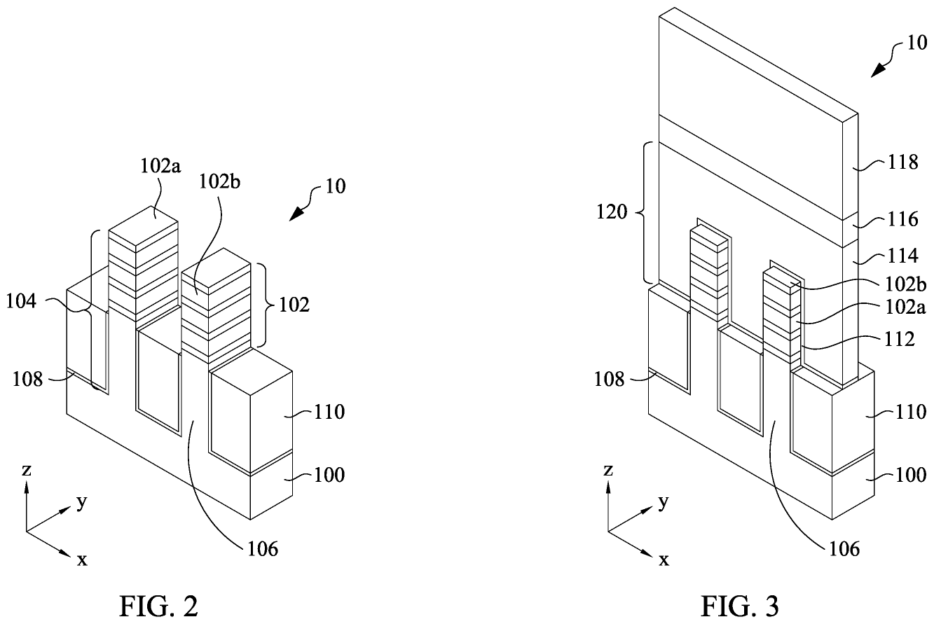

The stack of semiconductor layers 102 and a portion of the substrate 100 are then patterned to form into at least two semiconductor fins 104 as shown in FIG. 2. Each of the semiconductor fins 104 includes the well portion 106 formed by patterning the substrate 100 and one of the stacks of the semiconductor layers 102. To form the fin structures 104, a mask structure (not shown) may be formed on the stack of semiconductor layers 102. The mask structure may include an oxygen-containing layer and a nitrogen-containing layer. The oxygen-containing layer may be a pad oxide layer, such as a SiO₂ layer. The nitrogen-containing layer may be a pad nitride layer, such as Si₃N₄. The mask structure may be formed by any suitable deposition process, such as chemical vapor deposition (CVD) process or plasma enhance atomic layer deposition (PEALD).

A photoresist layer (not shown), for example, an oxide layer, is formed on the mask structure. The photoresist layer and the mask structure are then patterned to expose the underlying second semiconductor layers 102b of the stack of semiconductor layers 102. The photoresist layer may be formed by plasma enhance chemical vapor deposition (PECVD), for example. The exposed portions of the stack of semiconductor layers 102 are then removed until a predetermined thickness of the underlying substrate 10 is also removed. Each of the fin structures 104 may include the patterned stack of semiconductor layers 102 and a well portion 106 made from the substrate 10 under the patterned stack of semiconductor layers 102.

A conformal liner layer 108 may be formed over the substrate 100. That is, as shown in FIG. 2, the liner layer 108 is formed to cover the exposed surfaces of the well portions 106 and the exposed top surface of the substrate 10. In some embodiments, the liner layer 108 may be made of the same material as the substrate 100. The liner layer 108 may be formed by any suitable process, such as an atomic layer deposition (ALD) process. The term “conformal” May be used herein for ease of description upon a layer having substantial same thickness over various regions. The liner layer 108 may be made of silicon nitride, silicon oxynitride SiON, SiOCN, SiCN, fluorine-doped silicate glass (FSG), a low-K dielectric material, or any suitable dielectric material.

After formation of the liner layer 108, an insulating material 110 is formed on the substrate 100. The insulating material 110 partially fills the portions of the trenches at both sides of each semiconductor fin structure 104. For example, the insulating material 110 fills the portions between the neighboring well portions 106 of the corresponding semiconductor fins 104. In some embodiments, the insulation material 110 may be formed by suitable processes such as thermal oxidation to serve as shallow trench isolation (STI) with a top surface slightly lower than the top surface of the well portions 106. The mask structure and the photoresist layer are then removed to expose the stack of semiconductor layers 102.

FIG. 3 shows the process of forming the dummy gate structure. As shown, a conformal sacrificial dielectric layer 112 is formed on the exposed surfaces of the semiconductor structure 10, including the exposed surfaces of the STI 110 and the stack of semiconductor layers 102. The sacrificial dielectric layer 112 may include an oxide layer formed by flowable deposition such as flowable chemical vapor deposition (FCVD) or other suitable processes. A sacrificial gate electrode layer (or a dummy gate electrode layer) 114 is formed over the sacrificial dielectric layer 112 and filling the trenches between the stack of semiconductor layers 102. The dummy gate electrode layer 114 may be an amorphous silicon or polysilicon layer deposited by CVD, low pressure CVD (LPCVD), plasma-enhanced CVD (PECVD), Physical vapor deposition (PVD), ALD, sputter deposition, or other suitable deposition processes. A hard mask layer 116 is then formed over the dummy gate electrode layer 114. The hard mask layer 116 may be a nitrogen-containing layer such as silicon nitride, silicon oxide, silicon carbon-nitride, or multi-layers thereof. The mask layer 116 may be formed by PEALD or other suitable deposition processes.

Further in FIG. 3, a resist layer 118 is formed to pattern the hard mask layer 116, the sacrificial gate electrode layer 114, and the sacrificial gate dielectric layer 112. In one embodiment, the resister layer 118 may include an oxide layer formed by PEALD or other suitable processes. The dummy gate electrode layer 114 and the sacrificial gate dielectric layer 112 are then patterned using acceptable photolithography and etching techniques with the resist layer 118 as a mask. The resist layer 118 is removed after the sacrificial dielectric layer 112, the dummy gate electrode layer 114 and the hard mask layer 116 are patterned into a plate-like structure extending along the x-z plane. As shown in FIG. 3, the dummy gate structure 120 (including the sacrificial dielectric layer 112 and the patterned dummy gate electrode layer 114) and the hard mask 116 extends across the stack of semiconductor layers 102 along the x-direction.

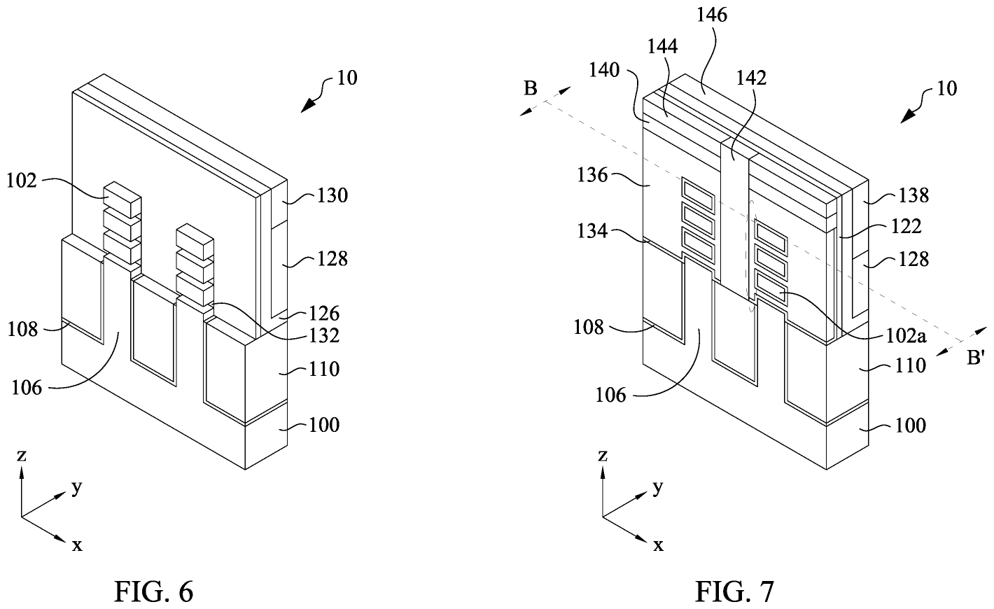

A gate spacer layer (122 as shown in FIG. 6) is formed on two opposite sidewalls of the dummy gate structure 120. In some embodiments, the gate spacer layer 122 may be formed of dielectric material such as Si₃N₄ layer formed by flowable CVD, ALD, or other suitable deposition processes. The gate spacer layer 122 may include a single-layer or multi-layer structure made of multiple dielectric layers. An etch process is then performed to remove the portions of the stacks of semiconductor layers 102 uncovered by the dummy gate structure 120. The exposed portions of the stacks of semiconductor layers 102 may be removed by an anisotropic until the underlying well portions 106 are exposed.

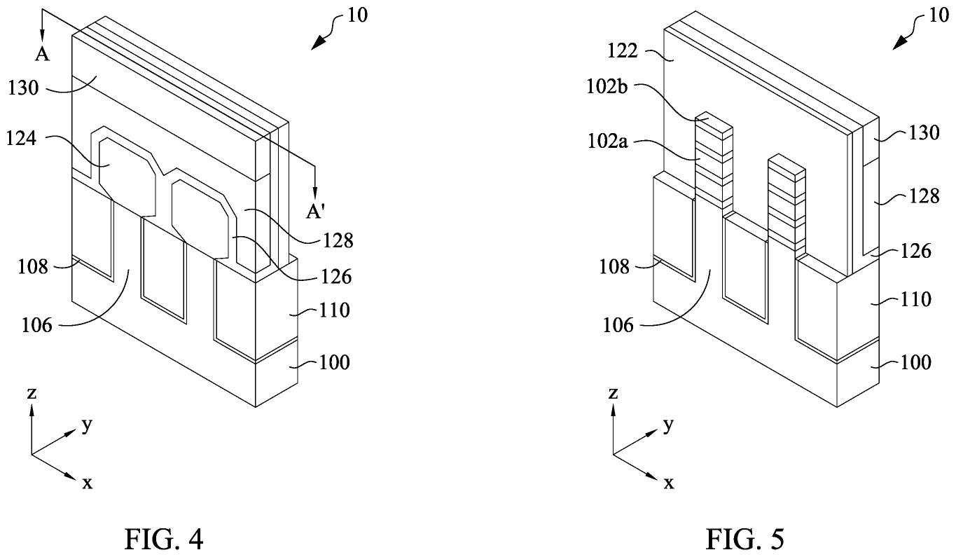

In FIG. 4, epitaxy regions, that is, source/drain regions, 124 are formed on the exposed well portions 104. Source/drain regions 124 may include silicon germanium SiGe or silicon Si. Depending on the conductive type of the FET to be formed, a p-type or an n-type dopant may be introduced with the epitaxy growth of the source/drain regions 124. For example, when a PFET is formed, silicon germanium boron SiGeB may be epitaxially grown. Alternatively, silicon phosphorous SiP or silicon carbon phosphorous SiCP may be epitaxially grown when an NFET is formed. In some embodiments, the source/drain regions 124 may be formed of a III-V semiconductor compound such as GaAs, InP, GaN, InGaAs, InAlAs, GaSb, Alsb, AlAs, AIP, GaP, or a combination or multilayer thereof. After the epitaxial growth, the source/drain regions 124 may be further implanted with a p-type or an n-type impurity. In some embodiments, the impurity implantation may be in-situ doped during the epitaxy growth of the source/drain regions 124.

Further in FIG. 4, a contact etch stop layer (CESL) 126 is conformally formed on the source/drain regions 124, and an interlayer dielectric (ILD) 128 is formed over the CESL 126. The CESL 126 may be formed of silicon nitride, silicon carbo-nitride, or the similar materials. In some embodiments, the CESL 126 may be oxygen free and formed using a conformal deposition process such as ALD or CVD, for example. The ILD 128 may be formed of SiO₂ based dielectric materials such as tetra ethyl ortho silicate (TEOS), PECVD SiO₂, phosphor-silicate glass (BSG), boron-doped phosphor-silicate glass (BPSG), or the similar materials. A hard mask layer 130 is then formed on the ILD 128. A planarization process such as chemical mechanical polish (CMP) process or a mechanical grinding process may be performed to level the top surface of hard mask layer, the gate spacer layer 122, and the dummy gate structure 120 as shown in FIG. 4.

FIG. 5 is a perspective view of the semiconductor device 10 extending along the x-z plane cut along the line A-A′ as shown in FIG. 4. As shown in FIG. 4, the line A-A′ extends along the x-direction between a pair of source/drain regions 124 formed at two opposite sides of the dummy gate structure 120. In FIG. 5, the hard mask layer 116 and the dummy gate structure 120 are removed to expose the remaining stack of semiconductor layers 102 extending between the pair of source/drain regions 124 at different positions in the y-direction.

In FIG. 6, the second semiconductor layers 102b are removed, leaving the first semiconductor layers 102a to serve as nanosheet channels. In some embodiments, before the semiconductor layers 102b are removed, the peripheral portions of each of the semiconductor layers 102b may be etched away to form cavities. The cavities may then be filled with high-k dielectric materials such as SiN, SiON, SiCON, or other suitable materials, to form the inner spacers 132. The second semiconductor layers 102b may be removed by an etch process using etchant that can selectively etch the second semiconductor layers 102b in accordance with some embodiments. For example, the second semiconductor layers 102b made of SiGe may be selectively removed using a wet etchant such as ammonium hydroxide (NH₄OH), tetramethylammonium hydroxide (TMAH), ethylenediamine pyrocatechol (EDP), or potassium hydroxide (KOH) solution.

As shown in FIG. 7, a gate dielectric layer 134 may be formed on the exposed surfaces of the semiconductor device 10. For example, the gate dielectric layer 134 may be formed to cover the exposed STI 110, well portion 106, and nanosheet channels 102a. In some embodiments, the gate dielectric layer 134 includes one or multiple layers of high-k dielectric materials such as silicon oxide, silicon nitride, and/or a combination thereof. Examples of the high-k dielectric materials may also include, but not limited to, HfO₂, HfSiO, HfSiON, HfTaO, HfTiO, zirconium oxide, aluminum oxide, titanium oxide, hafnium dioxide-alumina (HFO₂-AlₓO₃) alloy, or other suitable high-k materials. The gate dielectric layer 136 may be formed by CVD, ALD, or other suitable processes. In accordance with some embodiments, the gate dielectric layer 136 may be formed using a highly conformal deposition process such as ALD in order to ensure that formation of a gate dielectric layer 134 having a uniform thickness around each nanosheet channel layer 102a. The thickness of the gate dielectric layer 134 may range from about 1 nm to about 6 nm, for example.

A gate electrode layer 136 is then formed to surround each nanosheet channel layer 102a as shown in FIG. 7. The gate electrode layer 136 may include one or more layers of conductive materials, including polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, or any combinations thereof. The gate electrode layer 136 may be formed by CVD, ALD, electro-plating, or other suitable processes. In some embodiments, the gate electrode layer 136 may include a work function layer between the gate dielectric layer 134 and a metal layer enclosed by the work function layer. Depending on the device region, for example, an n-type device region or a p-type device region, the gate electrode layer 136 may include an n-type work function layer or a p-type work function layer, respectively.

A contact etch stop layer (CESL) 140 is formed on the gate electrode layer 136, and an ILD layer 144 is formed on the CESL 140. A cut metal gate (CMG) process is then performed to cut the metal gate structure, including the gate dielectric layer 134 and the gate electrode layer 136, into separate gate structures isolated by the CMG isolation structure 142. FIG. 8 shows a plane view of the semiconductor device 10 in an x-y plane cut along B-B′ line. In the embodiment as shown in FIG. 8, the sides of each of the nanosheet channels 102a along the x-direction are disposed against the corresponding S/D regions 124, while the sides of each of the nanosheet channels 102a along the y-direction are surrounded by the gate electrode layers 136. The CMG structure 142 is formed to extend through the ILD layer 144, the CESL 140, and the gate electrode layer 136 located between the neighboring stacks of nanosheet channels 142. As understood, during the CMG process, damage to the gate electrode layer 136 is inevitable. The damage may seriously impact the performance of the semiconductor device 10.

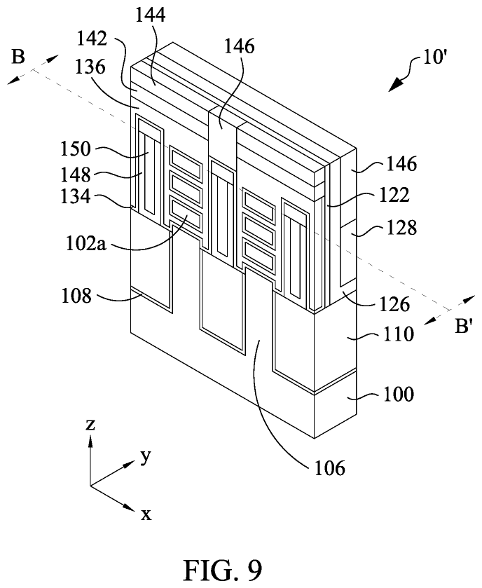

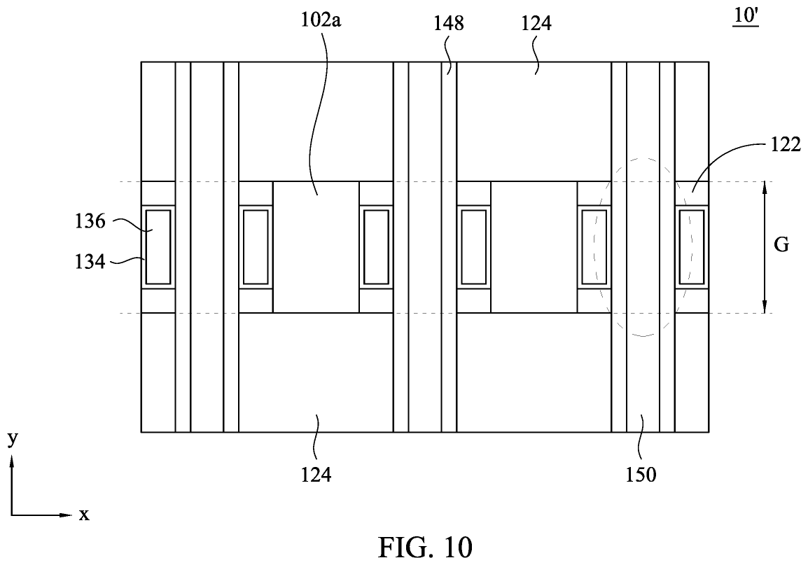

To improve the performance of the semiconductor device 10, the processes as shown in FIGS. 1-8 are modified as shown in FIGS. 9 and 10. In FIG. 9, a dielectric fin, that is, combination of dielectric layers 148 and 150 are formed between each pair of neighboring stacks of nanosheet channels 102a. The dielectric fin may be formed before forming the gate structure, including the gate dielectric layer 134 and the gate electrode layer 136. As the dielectric fin has been formed between the neighboring stacks of nanosheet channels 102a, no CMG process is performed at such locations. Therefore, the performance of the semiconductor device 10′ will not be degraded by damage of the gate electrode layer 136 between the nanosheet channels 102a. However, as the dielectric fin extends through the gate line G, the leakage between the metal gate and the contacts of the S/D regions becomes an issue in the areas denoted by the dash line as shown in FIG. 10.

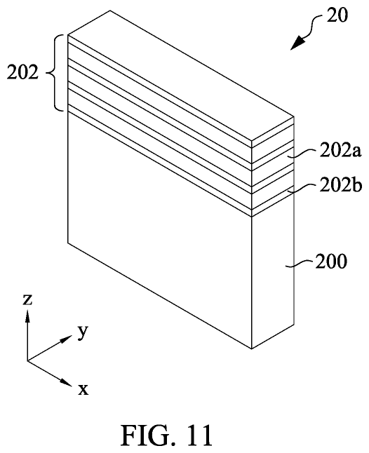

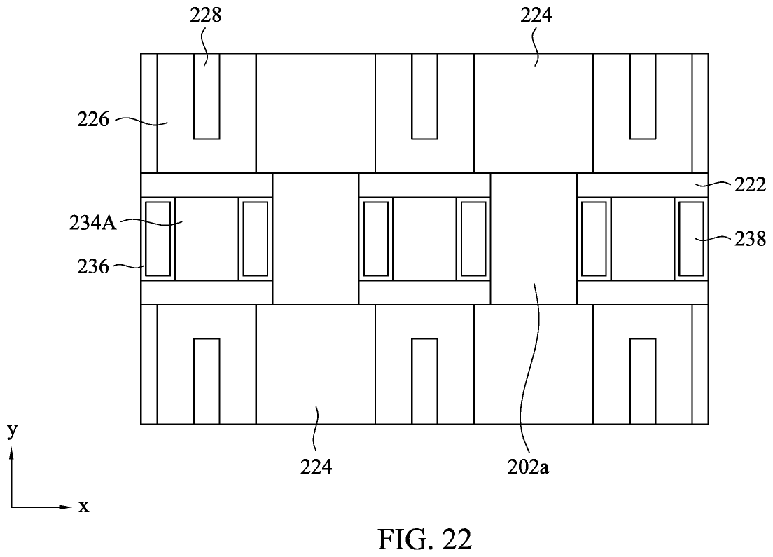

FIGS. 11 to 21 are perspective views showing various stages for manufacturing a nanosheet device according to some embodiments. FIG. 22 shows the plane view of the semiconductor structure as shown in FIG. 19. In FIG. 11, a substrate 200, such as the substrate 100 discussed above, is provided. In one embodiment, the substrate 200 is made of Si.

A stack of semiconductor layers 202, including alternately formed first semiconductor layers 202a and second semiconductor layers 202b, is formed on the substrate 200. The first semiconductor layers 202a and the second semiconductor layers 202b may be made of semiconductor materials having different etch selectivity and/or oxidation rates, such as the first semiconductor layers 102a and the second semiconductor layers 102b discussed above. In the embodiment as shown in FIG. 1, the first semiconductor layers 202a are made of Si and the second semiconductor layers 202b is made of Si₁₋ₓGeₓ with x ranging between about 25% and about 50%.

The first semiconductor layers 202a or portions thereof may form nanosheet channel(s) of the semiconductor device structure 20 in subsequent fabrication stages. The use of the first semiconductor layers 202a to define a channel or channels of the semiconductor device structure 20 is further discussed below.

The first and second semiconductor layers 202a and 202b may be formed by any suitable deposition process, such as epitaxy. In some embodiments, each semiconductor layer 202a has a thickness ranging from about 3 nanometers (nm) to about 10 nm. Likewise, each of the second semiconductor layers 202b may have a thickness that is equal to, less than, or greater than the thickness of the first semiconductor layers 202a, depending on device performance considerations. In one embodiment, each second semiconductor layers 202b has a thickness that smaller than the thickness of the semiconductor layers 202a.

In FIG. 11, the stack of semiconductor layers 202 includes three first semiconductor layers 202a and four second semiconductor layers 202b. It is appreciated that the numbers of the first and second semiconductor layers 202a and 202b in the stack of semiconductor layers 202 may vary depending on the desired number of nanosheet channels needed for the semiconductor structure 20. It is appreciated that the structure as shown in FIG. 11 May extend along the x-direction and/or the y-direction for forming an array of cell units on the substrate 20. The semiconductor structure 20 May be applied to a forksheet device which includes a PFET and an NFET arranged side by side along the x-direction at the same z-direction. In addition, the semiconductor structure 20 May also be applied to a complementary FET (CFET) device in which an additional stack of semiconductor layers is formed over the stack of semiconductor layers 202 at different levels in the z-direction.

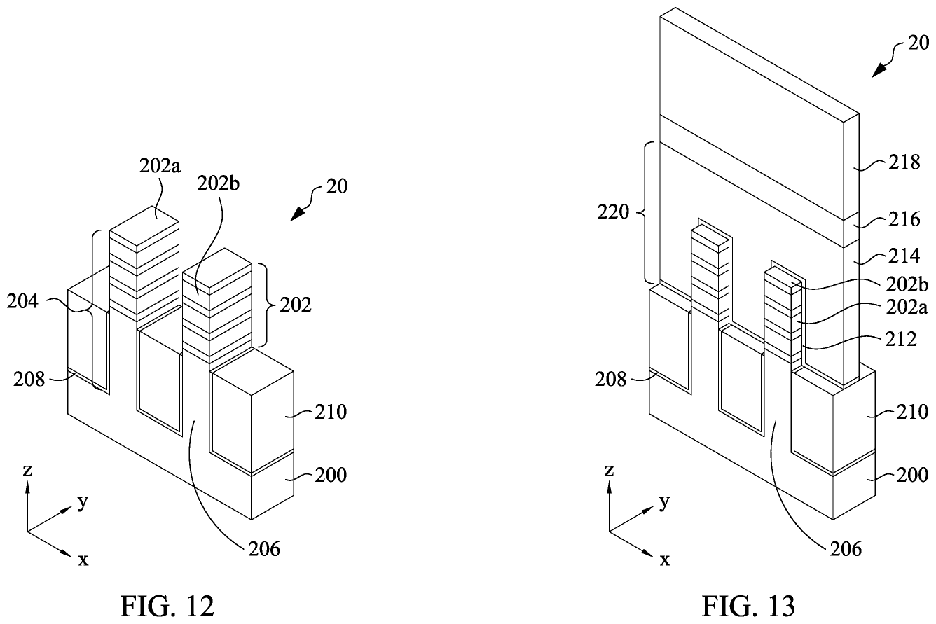

The stack of semiconductor layers 202 and a portion of the substrate 200 are then patterned to form into at least two semiconductor fin structures 204 as shown in FIG. 12. The semiconductor fin structures 204 may be formed using a similar fashion as discussed above with respect to FIG. 12. Each of the semiconductor fin structures 204 may include the patterned stack of semiconductor layers 102 and a well portion 206 made from the substrate 200 under the patterned stack of semiconductor layers 202.

A conformal liner layer 208, such as the liner layer 108, may be formed to cover the exposed surfaces of the well portions 206 and the substrate 20. In some embodiments, the liner layer 208 may be made of the same material as the substrate 200. After formation of the liner layer 208, an insulating material 210, such as the insulating material 110, is formed on the substrate 200. Likewise, the insulation material 210 may be formed by suitable processes such as thermal oxidation to serve as shallow trench isolation (STI) with a top surface slightly lower than the top surface of the well portions 206. The mask structure and the photoresist layer are then removed to expose the stack of semiconductor layers 202.

FIG. 13 shows the process of forming the dummy gate structure. As shown, a conformal sacrificial dielectric layer 212, such as the sacrificial dielectric layer 112, is formed on the exposed surfaces of the semiconductor structure 10, including the exposed surfaces of the STI 210 and the stack of semiconductor layers 202. A sacrificial gate electrode layer (or a dummy gate electrode layer) 214, such as the sacrificial gate electrode layer 114, is formed over the sacrificial dielectric layer 212 and filling the trenches between the stacks of semiconductor layers 202. A hard mask layer 216, such as the hard mask layer 116, is then formed over the dummy gate electrode layer 214. Then, a resist layer 218, such as the resist layer 118, is formed and patterned on the hard mask layer 116. The dummy gate electrode layer 214 and the sacrificial gate dielectric layer 212 are patterned using acceptable photolithography and etching techniques with the resist layer 218 as a mask. As shown in FIG. 13, the dummy gate structure 220 (including the sacrificial dielectric layer 212 and the patterned dummy gate electrode layer 214) and the hard mask layer 216 extend along the x-direction across the stacks of semiconductor layers 202. A gate spacer layer 222 (as shown in FIG. 15), such as the gate spacer layer 122, is formed on two opposite sidewalls of the dummy gate structure 220, in a similar fashion discussed above with respect to FIGS. 4 and 5.

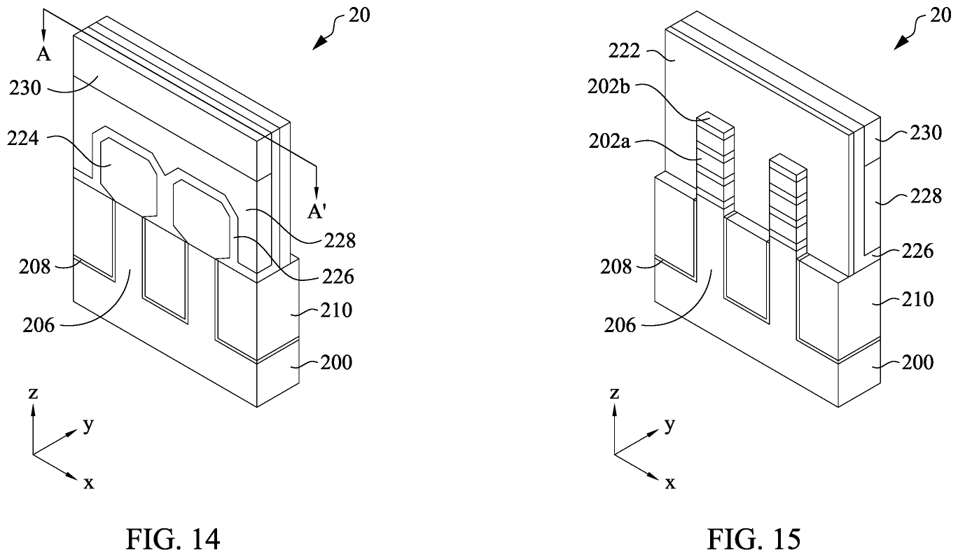

In FIG. 14, the stacks of semiconductor layers 102 uncovered by the dummy gate structures 220 are etched to expose the underlying well portions 206. Epitaxy regions, that is, source/drain regions 224, are formed on the exposed well portions 204. The source/drain regions 224 may include silicon germanium SiGe or silicon Si. Depending on the conductive type of the FET to be formed, a p-type or an n-type dopant may be introduced with the epitaxy growth of the source/drain regions 224. After the epitaxial growth, the source/drain regions may be further implanted with a p-type or an n-type impurity. In some embodiments, the impurity implantation may be in-situ doped during the epitaxy growth of the source/drain regions 224 and 226.

Further in FIG. 14, a contact etch stop layer (CESL) 226, such as the CESL 126, is conformally formed on the source/drain regions 224, and an interlayer dielectric (ILD) 228, such as the ILD 128, is formed over the CESL 226. A hard mask layer 230, such as the hard mask layer 130, is then formed on the ILD 228. A planarization process such as chemical mechanical polish (CMP) process or a mechanical grinding process may be performed to level the top surface of hard mask layer 230, the gate spacer layer 222, and the dummy gate structure 220 as shown in FIG. 14.

FIG. 15 is a perspective view of showing an interior portion of the semiconductor device 20 between a pair of the source/drain regions 224. The portion as shown in FIG. 15 extends on an x-z plane cut along the line A-A′ as shown in FIG. 14. In FIG. 15, the hard mask layer 216 and the dummy gate structure 220 are removed to expose the remaining stacks of semiconductor layers 202 extending between the pair of source/drain regions 224 (or 226) formed at different positions along the y-direction.

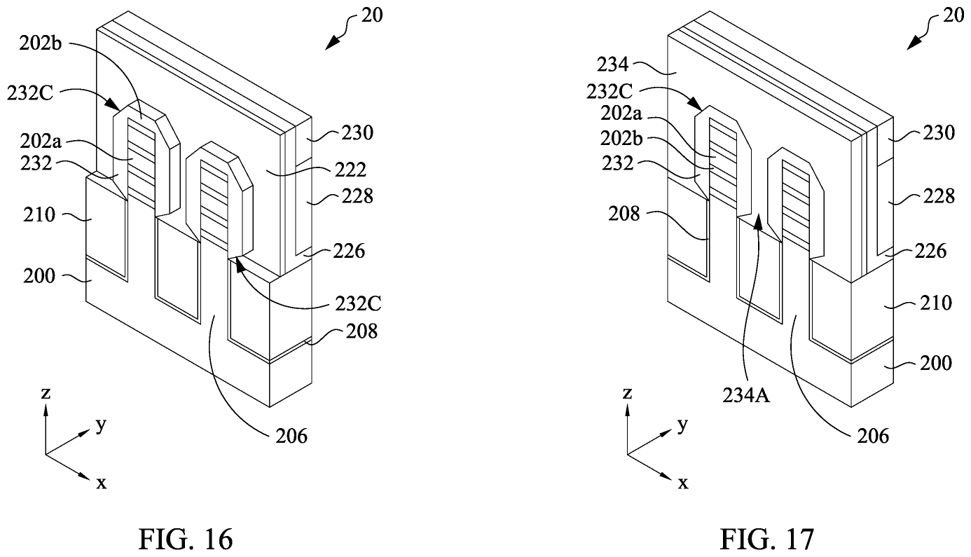

In FIG. 16, a semiconductor layer 232 is formed on the exposed surface of the stack of semiconductor layers 202. In some embodiments, the semiconductor layer 232 is conformally formed by the same materials for the second semiconductor layers 202b. The semiconductor layer 232 may also grow from the second semiconductor layers 202b. In the embodiment as shown in FIG. 16, the semiconductor layer 232 is epitaxially formed with SiGe (Si₁₋ₓGeₓ with x ranging between about 25% and about 50%). Single-crystal Si, SiGe, and Ge are members of three-dimensional lattice system referred to as the cubic lattice system. For a cubic lattice system, the top of a unit cell defines a (100) plane, the bottom surface is a (100) plane. Diagonal includes the (111) and (110) planes. The growth rate of Si, SiGe, and Ge depends on the orientations of the lattice planes. For example, the growth rate of the (100) is faster than other planes such as (110) and (111). As the SiGe is grown on the top surface with a rate different from those grown the sidewalls of the stacks of semiconductor layers 102, the corners 232C of the semiconductor layer 232 are formed to have tapered, beveled, or chamfered edges as shown in FIG. 16. In some embodiments, the semiconductor layer 232 and the topmost second semiconductor layer 202b are formed to have a substantially trapezoid profile. Similarly, the semiconductor layer 232 and the bottommost second semiconductor layer 202b may also be formed to have a substantially trapezoid profile. The semiconductor layers 202b may have a thickness ranging from about 0.5 nm to about 20 nm. In some embodiments, the semiconductor layers 202 may be formed with a thickness ranging from about 5 nm to about 10 nm.

After the formation of the semiconductor layer 232, a dielectric layer 234 is formed over the semiconductor device 20 and to fill the space around the semiconductor layer 232 as shown in FIG. 17. The dielectric layer 234 is then planarized by processes such as CMP or mechanical grinding. In some embodiments, the dielectric layer 234 may be formed from dielectric materials such as SiOCN which has high etching selectivity to the materials for forming the gate spacer layer 222 and the semiconductor layer 232.

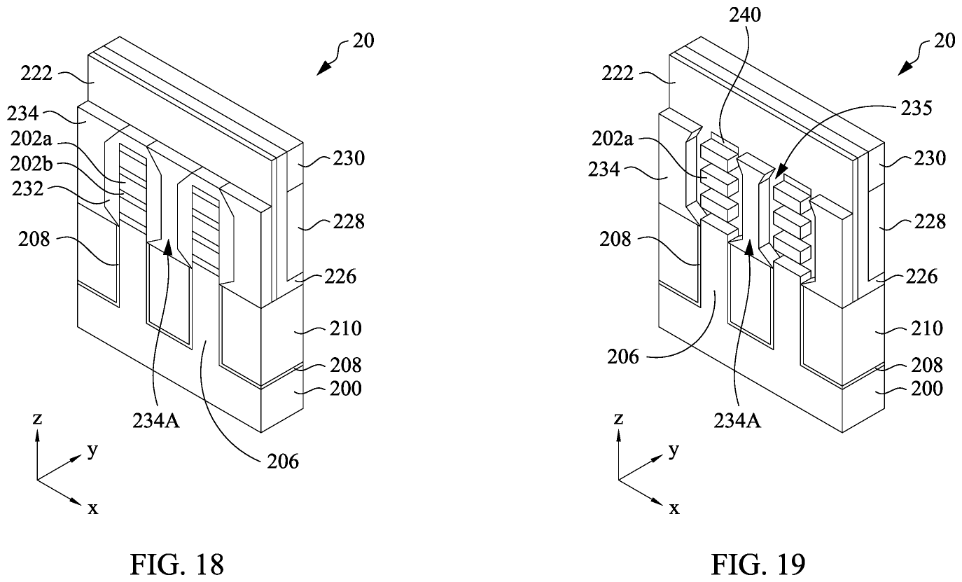

In FIG. 18, the dielectric layer 234 is etched to a predetermined level, for example, to the level where the top surfaces of the semiconductor layers 232 are exposed. In the embodiment as shown in FIG. 18, the dielectric layer 234 is etched into a plurality of separate dielectric fins 234, including the dielectric fin 234A between the pair of neighboring stacks of semiconductor layers 202.

In FIG. 19, the semiconductor layer 232 and the second semiconductor layers 202b are selectively removed to form the openings 235 in which the stack of first semiconductor layers 202a are exposed. The second semiconductor layers 202b and the semiconductor layer 232 may be removed by an etch process using etchant that can selectively etch the second semiconductor layers 202b. For example, the second semiconductor layers 202b made of SiGe may be selectively removed using a wet etchant such as ammonium hydroxide (NH₄OH), tetramethylammonium hydroxide (TMAH), ethylenediamine pyrocatechol (EDP), or potassium hydroxide (KOH) solution. As the epitaxially grown semiconductor layers 132 are formed with four chamfered edges at four corners thereof, the openings 235 formed after removal of the semiconductor layers 232 retains the chamfered-corner profile. The chamfered top corners of the opening 235 cause the remaining dielectric layer 234 have wider top and bottom portions and a recessed middle portion as shown in FIG. 19. An inner spacer 240 may be formed immediately above or below the periphery of each of the second semiconductor layers 202. The inner spacer 240 may be made of materials such as Si₃N₄, SiCO, SiO₂, SiON, Al₂O₃ using processes such as ALD, PEALD, or other suitable processes.

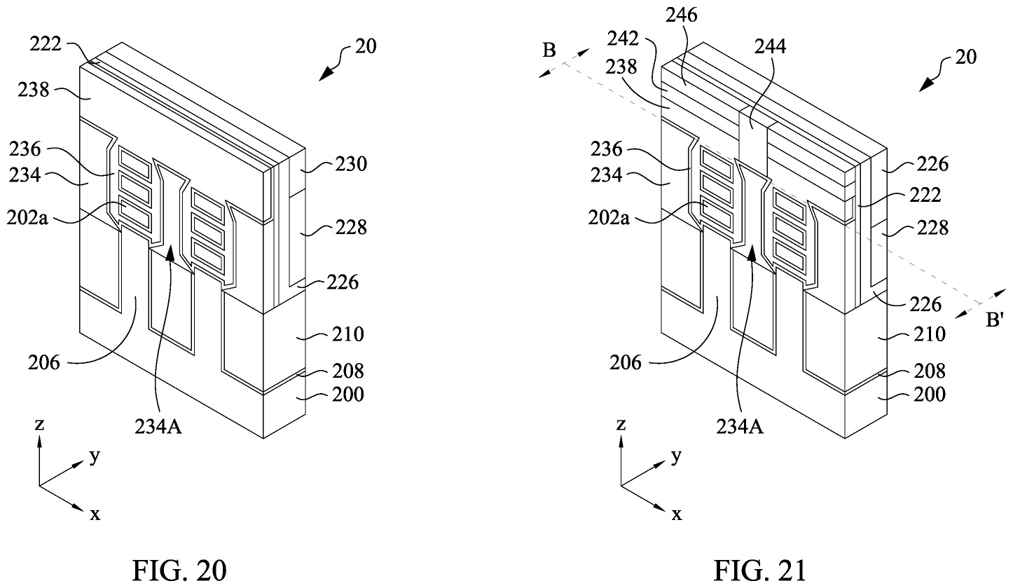

As shown in FIG. 20, a gate dielectric layer 236, such as the gate dielectric layer 136, is formed on the surfaces of the first semiconductor layers 202a (that is, the nanosheet channels) and the dielectric layer fins 234. In one embodiment, the gate dielectric layer 236 includes one or multiple layers of high-k dielectric materials such as silicon oxide, silicon nitride, and/or a combination thereof. The thickness of the gate dielectric layer 236 may range from about 1 nm to about 6 nm, for example.

A gate electrode layer 238, such as the gate electrode layer 138, is then formed over the semiconductor device 20 and filling the openings 235. The gate electrode layer 238 may be formed to surround each nanosheet channel layer 202a. Depending on the device region, for example, an n-type device region or a p-type device region, the gate electrode layer 238 may include an n-type work function layer or a p-type work function, respectively.

FIG. 21 is a perspective view showing the cut metal gate (CMG) process, where the gate electrode layer 238 is cut into separate metal gates and isolated by CMG structures 244. As shown in FIG. 21, a top portion of the gate electrode layer 238 is removed and recessed from a top surface of the semiconductor device 20. The top portion of the gate electrode layer 238 may be removed using an etching process selective to the materials, for example, conductive material or metals of the gate electrode without substantially attacking or removing other materials such as the gate spacer 222.

A contact etch stop layer (CESL) 242 may be formed on the recessed gate electrode layer 238, and an ILD layer 246 is formed over the CESL 242. In some embodiments, the CESL 242 is selectively formed on the gate electrode layer 238 to help reduce the electrical resistance of the gate structure and/or gate contact plugs formed in the subsequent processes. The CESL 242 may be a fluorine-free tungsten (FFW) layer, for example. The gate electrode layer 238 may be patterned with an opening exposing the dielectric fin 234A located between the neighboring stacks of nanosheet channels 202. The opening is then filled with dielectric material to form the CMG structure 244 as shown in FIG. 21. In the subsequent processes, metal contacts, for example, the source/drain (S/D) contacts 236 and gate contacts (not shown) may be formed. In some embodiments, the CMG structure 244 may be made of high-k dielectric materials such as SiN, SiON, SiOCN, SiON, or a combination thereof. The materials of the CMG structure 244 may also selected from the same materials for forming the dielectric layer 234 in accordance with some embodiments. In some embodiment, the dielectric fin 234A connected with the CMG structure 244 functions as a part of the CMG structure 244 for the metal gate isolation.

FIG. 22 shows a plane view of the semiconductor device 20 cutting along B-B′ cutting line in an x-y plane. Each of the nanosheets channels 102a is connected with a pair of S/D regions 124 along the y-direction and adjacent to the metal gates 238 along the x-direction, while the metal gate 238 between each pair of the nanosheet channels 202a is divided into two isolated portions by the dielectric fin 234A. The wider top surface of the dielectric fin 234A results in a larger window for CMG window. As the dielectric fin 234A is formed without CMG process, no cut metal damage occurs in the area between the neighboring nanosheet channels 202a. The product performance is thus effectively enhanced. The oxide-definition (OD) can thus be further scaled. The leakage between the metal gate and the S/D contacts with the structures as shown in FIGS. 9 and 10 is no longer a concern as the dielectric fin does not extend through the metal gate and the S/D contacts. In addition, referring to FIG. 21, the tapered corners of the gate electrode layer 238 reduces the contact areas with the well portion 206. The reduced contact areas not only minimize the current leakage, but also enhances the electric performance by reducing the workload of the semiconductor device.

According to some embodiments, a method of forming a semiconductor structure is provided. The method comprises forming a pair of stacks of semiconductor layers each including a plurality of first semiconductor layers and a plurality of second semiconductor layers alternately stacked with each other along a first direction. The pair of stacks of semiconductor layers are adjacent to each other along a second direction. A pair of epitaxial regions is formed at two opposite ends of each stack of semiconductor layers along a third direction. A conformal semiconductor layer is formed on each stack of semiconductor layers. A space between the pair of stacks of semiconductor layers is filled with a dielectric fin. The conformal semiconductor layer and the second semiconductors are removed. A gate electrode layer is formed over the stacks of semiconductor layers. The gate electrode layer may fill openings created by removal of the conformal semiconductor layers and the second semiconductor layers. In some embodiments, the first semiconductor layers are formed from Si and the second semiconductor layers are formed from SiGe. The first and second semiconductors may be epitaxially grown from a semiconductor substrate. The conformal semiconductor layer may be made of epitaxy SiGe. The conformal semiconductor layer may have a thickness of about 5 nm to about 10 nm.

In some embodiments, the conformal semiconductor layer may be epitaxially grown on exposed surfaces of each of the stacks of semiconductor layers. The conformal semiconductor layer may have four tapered corners. The dielectric fin may have a top surface and a bottom surface larger than a central portion thereof. The epitaxy regions may be source/drain regions. A gate dielectric layer may be formed before forming the gate electrode layer. The method may further comprise performing a cut metal gate process on the gate electrode layer. A cut metal gate structure may be formed on the dielectric fin. The first direction, the second direction, and the third direction may extend along three orthogonal axes in a 3-dimensional coordinate.

A method for forming a nanosheet device is provided in accordance with another embodiment. The method includes epitaxially growing a conformal semiconductor layer from a first stack of semiconductor layers and a second stack of the semiconductor layers. Each of the first and second stack of semiconductor layers includes a plurality of first semiconductor layers and a plurality of second semiconductor layers alternately stacked on each other. A space between the first and second stacks of semiconductor layers may be filled with a dielectric fin. The conformal semiconductor layer and the second semiconductor layers may be removed. A metal gate structure is formed over the first semiconductor layer and filling openings created by removal of the conformal semiconductor layer and the second semiconductor layer. A process may be performed on the metal gate structure to form an isolation between the portions of the metal gate structure being separated by a patterning process. The conformal semiconductor layer may be formed with four tapered corners. A portion of the metal gate structure filling the openings has four tapered corners. The dielectric fin has a wider top surface, a wider bottom surface, and a narrower middle body extending between the top and bottom surfaces.

A semiconductor structure is provided according to yet another embodiment. The semiconductor structure includes a pair of nanosheet channel structures, each of the nanosheet channel structures including a plurality of nanosheet channels spaced apart with other along a vertical direction. A dielectric fin is formed to extend between the pair of nanosheet channel structures. The dielectric fin has a top surface at a level higher than a top surface of each of the nanosheet channel structures. A metal gate structure is formed over the pair of nanosheet channels and the dielectric fin. The metal gate structure may fill spaces between the dielectric fin and the pair of nanosheet channel structures. The semiconductor structure may further comprise a cut-metal-gate isolation structure formed on the top surface of the dielectric fin.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of forming a semiconductor structure, comprising:
forming a pair of stacks of semiconductor layers each including a plurality of first semiconductor layers and a plurality of second semiconductor layers alternately stacked with each other along a first direction, wherein the pair of stacks of semiconductor layers are adjacent to each other along a second direction;
forming a pair of epitaxial regions at two opposite ends of each stack of semiconductor layers along a third direction;
forming a conformal semiconductor layer on each stack of semiconductor layers;
filling a space between pair of stacks of semiconductor layers with a dielectric fin;
removing the conformal semiconductor layer and the second semiconductors; and
forming a gate electrode layer over the stacks of semiconductor layers, the gate electrode layer filling openings created by removal of the conformal semiconductor layers and the second semiconductor layers.

2. The method of claim 1, further comprising forming the first semiconductor layers with Si and the second semiconductor layers with SiGe.

3. The method of claim 2, further comprising epitaxially forming first and second semiconductors.

4. The method of claim 2, further comprising the conformal semiconductor layer with SiGe.

5. The method of claim 1, further comprising forming the conformal semiconductor layer with a thickness of about 5 nm to about 10 nm.

6. The method of claim 1, further comprising epitaxially growing the conformal semiconductor layer on exposed surfaces of the stacks of semiconductor layers.

7. The method of claim 1, further comprising forming the conformal semiconductor layer with four tapered corners.

8. The method of claim 1, further comprising forming the dielectric fin with a top surface and a bottom surface larger than a central portion thereof.

9. The method of claim 1, wherein the epitaxy regions include source/drain regions.

10. The method of claim 1, further comprising forming a gate dielectric layer before forming the gate electrode layer.

11. The method of claim 1, further comprising patterning the gate electrode layer into a plurality of separate gate structures.

12. The method of claim 11, further comprising forming an isolation structure on the dielectric fin.

13. The method of claim 1, wherein the first direction, the second direction, and the third direction extend along three orthogonal axes in a 3-dimensional coordinate.

14. A method for forming a nanosheet device, comprising:
epitaxially growing a conformal semiconductor layer from a first stack of semiconductor layers and a second stack of the semiconductor layers, wherein each of the first and second stack of semiconductor layers includes a plurality of first semiconductor layers and a plurality of second semiconductor layers alternately stacked on each other;
filling a space between the first and second stacks of semiconductor layers with a dielectric fin;
removing the conformal semiconductor layer and the second semiconductor layers; and
forming a metal gate structure over the first semiconductor layers and the dielectric fin, the metal gate structure filling openings created by removal of the conformal semiconductor layer and the second semiconductor layers.

15. The method of claim 14, further comprising performing a process on the metal gate structure to form an isolation between the portions of the metal gate structure being separated by a patterning process.

16. The method of claim 15, further comprising forming the conformal semiconductor layer with four tapered corners.

17. The method of claim 16, wherein a portion of the metal gate structure filling the openings has four tapered corners.

18. The method of claim 17, further comprising the dielectric fin with a wider top surface, a wider bottom surface, and a narrower middle body extending between the top and bottom surfaces.

19. A semiconductor structure, comprising:
a pair of nanosheet channel structures, each of the nanosheet channel structures including a plurality of nanosheet channels spaced apart with other along a vertical direction;
a dielectric fin extending between the pair of nanosheet channel structures, wherein the dielectric fin has a top surface at a level higher than a top surface of each of the nanosheet channel structures; and
a metal gate structure formed over the pair of nanosheet channels and the dielectric fin, the metal gate structure being formed to fill spaces between the dielectric fin and the pair of nanosheet channel structures.

20. The semiconductor structure of claim 19, further comprising an isolation structure formed on the top surface of the dielectric fin.
